(19) United States
(12) Patent Application Publication
(10) Pub. No.: US 2016/0339428 A1
(43) Pub. Date: Nov. 24, 2016

(54) SYSTEM AND METHOD FOR CHEMICALLY PATTERNED PAPER MICROFLUIDIC DEVICES

(71) Applicant: Texas Tech University System, Lubbock, TX (US)

(72) Inventors: Jungkyu Kim, Lubbock, TX (US); Ryan Howse, El Paso, TX (US)

(73) Assignee: Texas Tech University System, Lubbock, TX (US)

(21) Appl. No.: 15/135,326

(22) Filed: Apr. 21, 2016

Related U.S. Application Data
(60) Provisional application No. 62/150,387, filed on Apr. 21, 2015.

(51) Int. Cl. B01L 3/00; C23C 16/04; C23C 16/30

(52) U.S. Cl. CPC B01L 3/502707; C23C 16/30; C23C 16/04; B01L 3/50273; B01L 2300/126; B01L 2300/0867; B01L 2200/12; B01L 2300/0887

(57) ABSTRACT

Disclosed is a device and method for forming a chemically patterned paper microfluidic device (cPMD) having controllable hydrophobic regions for purposes of providing a repeatable and versatile production with no temperature limitations similar or expensive printers, enabling point of care sensor devices. The disclosed invention comprises multilayer capability, including the ability for various biomolecules to be immobilized with charge interaction. The paper-based microfluidic platform as disclosed repeatable, versatile, cost effective, and allows for the creation of complex channels using the settling time calculated from calibration results. The disclosed system supports a wide variety of scenarios for testing, diagnostics and drug delivery, and related products and services.

### CROSS-REFERENCE TO RELATED APPLICATIONS

This application claims priority to: provisional U.S. Patent Application Ser. No. 62/150,387, filed on Apr. 21, 2015, entitled “System and Method for Chemically Patterned Paper Microfluidic Devices” which provisional patent application is commonly assigned to the Assignee of the present invention and is hereby incorporated herein by reference in its entirety for all purposes.

This application includes material that is subject to copyright protection. The copyright owner has no objection to the facsimile reproduction by anyone of the patent disclosure, as it appears in the Patent and Trademark Office files or records, but otherwise reserves all copyright rights whatsoever.

### TECHNICAL FIELD

The present invention relates in general to the field of microfluidic devices. In particular, the system of the present invention provides for a microfluidic devices comprised of chemically patterned paper. The disclosed systems and methods support a wide variety of scenarios for diagnostic research and related products and services.

### STATEMENT OF FEDERALLY FUNDED RESEARCH

None.

### BACKGROUND OF THE DISCLOSURE

Dipstick and lateral-flow formats have dominated rapid diagnostics over the last three decades. These formats gained popularity in the consumer markets due to their compactness, portability and facile interpretation without external instrumentation. However, lack of quantitation in measurements has challenged the demand of existing assay formats in consumer markets. Recently, paper-based microfluidics has emerged as a multiplexable point-of-care platform which might transcend the capabilities of existing assays in resource-limited settings. This technology is being utilized for medical screening, point-of-care (POC) applications, and environmental monitoring. However, most of these devices still require expensive equipment or personnel with significant training.

Current industry microfluidics devices are expensive benchtop analyzers or disposable tests with limited capacity. The benchtop systems, although extremely accurate, are expensive, require highly trained personnel, and results take a long time to gather. The disposable tests available are only qualitative and therefore have low sensitivity.

There is currently a need for cost effective screening devices, especially in third world countries. Despite advances in the art, there remains a need to improve biomimetic valvular systems for purposes of these advanced models for research.

### SUMMARY OF THE DISCLOSURE

It is therefore an object of the present invention to provide a chemically-patterned paper microfluidic device (cPMD) having controllable hydrophobic regions for purposes of providing a repeatable and versatile production system having no temperature limitations similar to current art, nor expensive printers, allowing point of care sensor devices which may be handheld and real time rather than requiring the use of benchtop systems. The cPMD can be used for a vast range of biomedical and environmental applications. The wicking forces of the paper including capillary action and surface tension generate fluid flow without the need for external pumps. By vaporizing trichlorosilane (TCS) in a vacuum chamber with the cPMD inside, hydrophobic barriers can be created around the channel of interest. The versatility of this platform allows for an endless combination of channel structures, including both 2D and 3D networks. The 3D networks can be fabricated by chemical vapor disposition (CVD) of TCS on the cPMD device and stacking multiple layers paper. This type of sensor can potentially be used for detecting tuberculosis, lead concentration in drinking water, and many more applications.

This present invention will eliminate the need for expensive equipment and specially trained personnel to analyze the results. The cPMD device solves both of these issues. The paper platform significantly reduces the cost of manufacturing and the small sample volume reduces waste. The benchtop systems are eliminated by the use of cell phones which provide quantitative results with high sensitivity. In addition, because the user can perform all of the tasks by simply reading the provided instructions, results can be gathered significantly faster. The advances in cell phone technology will also increase the versatility of this innovative platform with enhanced imaging cameras and interconnectivity.

The cPMD of the present invention uses CVD to alter the properties of the paper precisely in areas of interest. Other methods only block portions of paper by using hydrophobic barriers such as melted wax. In addition, because the wax must be melted, it is susceptible to deformed channels in the presence of higher temperatures which compromises the performance of the sensor. The cPMD platform is unaffected by increased temperatures and does not require expensive precision printers. Also, the cPMD device is completely self-contained, meaning that it does not require external power to generate fluidics movement. This eliminates the need for electronics and specialized results readers. Instead, all the results can be completely analyzed with a mobile handheld device, such as a smart phone. Lastly, the cPMD of the present invention leaves a small foot-print on the environment because it is based on paper. This allows for the device to be much easier to dispose than other microfluidic methods.

It is thus one object of the present invention to provide a method for preparing a chemically patterned microfluidic device, comprised by: providing a chemical vapor deposition (CVD) reactor chamber; positioning within the chemical vapor deposition (CVD) reactor chamber a substrate; and forming over the substrate a silane layer, said silane layer comprising at minimum a first reactant source material introduced into the reactor chamber. The reactant source material may be trichlorosilane. The reactor chamber may further be a vacuum chamber. The purpose of the silane layer is to create a hydrophobic portion of the cPMD wherein the water contact angle may be generally greater than 120 degrees, or more particularly, greater than 135 degrees. In one aspect, the temperature on the surface of the reactor chamber is from 10 deg. C. to 100 deg. C. In another aspect, the temperature on the surface of the reactor chamber is 60 deg. C. The substrate may comprise a porous membrane, and may be chromatographic paper, or may have multiple layers such as chromatographic paper, nitrocellulose, and combinations thereof.

The method may further comprising incorporating capture agents into the channels, which can be selected from the group consisting of: a protein, an antibody, an enzyme, and immunoactive fragment, an allergen, DNA, RNA, aptamers, or combinations thereof

It is another object of the present invention to provide a reactor chamber which is a vacuum chamber. The temperature on the surface of the reactor chamber can range from 10 deg. C. to 100 deg. C., such as 60 deg. C.

It is another object of the present invention to provide a method for preparing a chemically patterned microfluidic device, comprising: providing a chemical vapor deposition (CVD) reactor chamber; positioning within the chemical vapor deposition (CVD) reactor chamber a substrate; and forming over the substrate a layer comprising at minimum a first reactant source material introduced into the reactor chamber.

It is another object of the present invention to provide a chemically patterned microfluidic device, comprising a porous membrane substrate having at least one channel, wherein said substrate further comprises a deposited functional layer. The porous membrane substrate may be a paper such as chromatography paper. The functional layer may be a hydrophobic layer, such as a silane, including trichlorosilane, and the like, and said deposited functional layer may have a water contact angle greater than 120 degrees, or greater than 135 degrees.

It is another object of the present invention to provide a device having at least one channel that is functionalized with a capture agent selected from the group consisting of: a protein, an antibody, an enzyme, an immunoactive fragment, an allergen, DNA, RNA, aptamers, or combinations thereof. Additionally, the device or channels within the device may comprise multilayer substrate having more than one layer of substrate selected from group consisting of: chromatographic paper and nitrocellulose.

It is another object of the present invention to provide a chemically patterned microfluidic device (cPMD), comprising at least one channel having hydrophobic barriers, wherein said hydrophobic barriers further comprise a hydrophobic silane layer, such as trichlorosilane. The cPMD may comprise a sensor device, which may be wearable, such as a diagnostic watch affixed to a user's wrist, and may further comprise a computing device for quantitative measurement of the reaction of fluid within the at least one channel and display via a display screen.

This area of microfluidics accounts for a large share of the microfluidics market and is expected to grow rapidly. The growth of this industry is from a desire to treat patients outside of traditional settings such as hospitals, reduce the volume of samples, and decreased time to determine results. The in-vitro diagnostics segment of microfluidic products market is expected to drive the need for higher sensitivity devices, and faster analysis.

### BRIEF DESCRIPTION OF THE DRAWINGS

The foregoing and other objects, features, and advantages of the disclosure are apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 depicts a chemical application setup for the system of the present invention.

FIG. 2 depicts a demonstrative single-input multiple output sample of the present invention.

FIG. 3 depicts a graphical description of copper ion concentration versus integrated color density results.

FIG. 4 depicts a diagram of a wearable point of care diagnostic sensor device of the present invention.

FIG. 5 depicts a flow diagram of a method of the present invention.

FIG. 6 depicts an exemplary methodology for paper-based microfluidic production using the method of the present invention.

FIG. 7A depicts characterization of the front side of the patterned chromatography paper treated in accordance with the present invention at 15 seconds settling time.

FIG. 7B depicts characterization of the back side of the patterned chromatography paper treated in accordance with the present invention at 15 seconds settling time.

FIG. 7C depicts a graph showing differing dimensions of channels (4, 3, 2, 1 mm width×10 mm length) using different settling times.

FIG. 8A-F depicts a series of volumetric flow rates on normal paper and patterned fluidic device of the present invention.

FIG. 9A depicts an exemplary glucose array for a spot-patterned device of the present invention.

FIG. 9B depicts a graph showing glucose assay results of the FIG. 9A pattern.

FIG. 10A depicts an exemplary inflow glucose array.

FIG. 10B depicts a graph showing glucose assay results of the FIG. 10A inflow array.

FIG. 10C depicts a graph showing absorbance obtained from 96 well plate and differential RGB values.

FIG. 11A depicts a differential immunoassay on a well spot patterned device of the present invention.

FIG. 11B depicts a graph showing immunoassay array results from the FIG. 9A spot pattern.

FIG. 12 depicts a device of the present invention comprising a nitrocellulose layer.

### DETAILED DESCRIPTION OF THE DISCLOSURE

While the making and using of various embodiments of the present invention are discussed in detail below, it should be appreciated that the present invention provides many applicable inventive concepts that can be embodied in a wide variety of specific contexts, goods, or services. The specific embodiments discussed herein are merely illustrative of specific ways to make and use the disclosure and do not delimit the scope of the disclosure.

All publications and patent applications mentioned in the specification are indicative of the level of skill of those skilled in the art to which this disclosure pertains. All publications and patent applications are herein incorporated by reference to the same extent as if each individual publication or patent application was specifically and individually indicated to be incorporated by reference.

The present invention will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Turning to the present invention, advances in technology have allowed the human race to detect viruses, bacteria, and harmful environmental chemicals more precisely. However, the methods used to perform these tasks require highly specialized personnel and expensive equipment. In analysis of proteins and enzymes, microfluidic design has proven to be a powerful technological tool to improve performance of immunoassays, enzymatic reactors, and other biological assays. Importantly, manipulation of liquid inside microscale fluidic networks enables reduced consumption of reagents, compared to macroscale instruments.

Microfluidics is a multidisciplinary field intersecting engineering, physics, chemistry, biochemistry, nanotechnology, and biotechnology, with practical applications to the design of systems in which low volumes of fluids are processed to achieve multiplexing, automation, and high-throughput screening. Microfluidics emerged in the beginning of the 1980s and is used in the development of inkjet printheads, DNA chips, lab-on-a-chip technology, micro-propulsion, and micro-thermal technologies. It deals with the behavior, precise control and manipulation of fluids that are geometrically constrained to a small, typically sub-millimeter, scale. Typically, micro means one of the following features: (i) small volumes (μL, nL, pL, fL), (ii) small size, (iii) low energy consumption, and (iv) effects of the micro domain.

Typically fluids are moved, mixed, separated or otherwise processed. Numerous applications employ passive fluid control techniques like capillary forces. In some applications external actuation means are additionally used for a directed transport of the media. Examples are rotary drives applying centrifugal forces for the fluid transport on the passive chips. Active microfluidics refers to the defined manipulation of the working fluid by active (micro) components such as micropumps or micro valves. Micro pumps supply fluids in a continuous manner or are used for dosing. Micro valves determine the flow direction or the mode of movement of pumped liquids. Often processes which are normally carried out in a lab are miniaturized on a single chip in order to enhance efficiency and mobility as well as reducing sample and reagent volumes.

Microfluidic structures include micropneumatic systems, i.e. microsystems for the handling of off-chip fluids (liquid pumps, gas valves, etc.), and microfluidic structures for the on-chip handling of nano- and picolitre volumes. To date, the most successful commercial application of microfluidics is the inkjet printhead. Significant research has also been applied to microfluidic synthesis and production of various biofunctionalized nanoparticles including quantum dots (QDs) and metallic nanoparticles, and other industrially relevant materials (e.g., polymer particles). Additionally, advances in microfluidic manufacturing allow the devices to be produced in low-cost plastics and part quality may be verified automatically. An emerging application area for biochips is clinical pathology, especially the immediate point-of-care diagnosis of diseases. In addition, microfluidics-based devices, capable of continuous sampling and real-time testing of air/water samples for biochemical toxins and other dangerous pathogens, can serve as an alarm for early warning. Microfluidic devices may be continuous-flow, chip-based, droplet-based, digital, microarrays, optics, acoustic droplet injection, fuel cells and the like.

Decreased liquid volume and short diffusion lengths allow facile reactions between analyte and antibody or enzyme and substrate, resulting in reduced assay times with microfluidic assays. Over the past decade the interest in paper-based microfluidics has risen significantly. Currently, wax printing is the most popular fabrication method due to its high throughput and channel precision as low as 600 microns. This method is susceptible to heat which can distort the wax barrier and compromise the channel, and the cost of the wax printer is relatively high. The present invention present an improved chemical patterning technique that is unaffected by heat which is required for certain applications, and does not require expensive printers.

In one embodiment a system for producing a chemically patterned microfluidic device (cPMD) comprises chemical vapor deposition (CVD), a chemical process used to produce high quality, high-performance, solid materials wherein a substrate is exposed to one or more volatile precursors, which react and/or decompose on the substrate surface to produce the desired deposited layer. Frequently, volatile by-products are also produced, which are removed by gas flow through the reaction chamber. CVD is practiced in a variety of formats. These processes generally differ in the means by which chemical reactions are initiated. CVD may be further classified by operating pressure, including atmospheric pressure CVD-CVD at atmospheric pressure, low-pressure CVD-CVD at sub-atmospheric pressures or ultrahigh vacuum CVD-CVD at very low pressure, typically below 10−6 Pa (˜10−8 ton). Reduced pressures tend to reduce unwanted gas-phase reactions and improve film uniformity across the wafer. There may be a lower division between high and ultra-high vacuum is common, often 10−7 Pa.

CVD may be further classified by physical characteristics of the vapor, such as aerosol-assisted CVD, or direct liquid injection CVD. In other instances, the methods of deposition, such as microwave plasma-assisted CVD, plasma-enhanced CVD, remote plasma-enhanced CVD, atomic layer CVD, combustion chemical vapor deposition, hot filament CVD, hybrid chemical vapor deposition, metalorganic chemical vapor deposition, rapid thermal CVD, vapor phase epitaxy, and photo-initiated CVD may be utilized. As such the term CVD is presented as a non-limiting term for the various types of CVD presented herein as a process for augmenting substrate surfaces in ways that more traditional surface modification techniques are not capable of, especially at depositing extremely thin layers of material.

CVD may be used to react source materials in various forms, such as monocrystalline, polycrystalline, amorphous, and epitaxial. The reactant source materials utilized in CVD processes include: silanes, carbon fiber, carbon nanofibers, fluoropolymers, graphene, filaments, carbon nanotubes, S102, silicon-germanium, tungsten, silicon carbide, silicon nitride, silicon oxynitride, titanium nitride, and various high-k dielectrics. In an exemplary embodiment of the present invention, a cPMD is coated in a hydrophobic layer, such as trichlorosilane (TCS), to create hydrophobic and hydrophilic regions having various successful patterns and bioassays depending on the desired use, which includes a sensor device comprising cPMD.

For the purposes of the present invention, the examples of a sensor device may include, but is not limited to: bioassays and biological procedures such as biomedical screening of diseases, DNA sequencing, electrophoresis, DNA separation, enzymatic assays, immunoassays, cell counting, cell sorting, and cell culture. Electrophoresis is a versatile analytical technique which is successfully used for the separation of small ions, neutral molecules, and large biomolecules. It is being utilized in widely different fields, such as analytical chemistry, clinical chemistry, organic chemistry, and pharmaceuticals. The sensor device may further be applied to general sensing in the medical fields, and environmental testing, such as water quality testing and environmental monitoring.

Most paper-based microfluidic devices require expensive equipment such as inkjet printers, or photolithography machines. The cPMD platform only requires inexpensive vacuum chambers, and low volumes of chemicals. This allows for these types of devices to be fabricated in any setting. Additionally, another common method currently being used for such devices is wax printing. Some chemical reactions require heat which would ruin the integrity of the hydrophobic barriers which destroys the microfluidic channels. The performance of the cPMD device is not affected by heat. Typically, paper-based microfluidic devices are inherently qualitative which severely limits the sensitivity of the device. This type of measurement is subjective to the user and can create false results. The sensitivity of the cPMD of the present invention can be quantitative if paired with a cell phone camera. By creating mobile applications, the user may make quantitative analysis by taking a picture of the results and comparing the picture to a preset calibration. In addition, the results could be sent to a doctor to further diagnose the sample.

The cPMD method of the present invention allows for vaporized TCS to completely cover the paper where hydrophobic properties are necessary. The deposited molecules, which may be TCS, become impregnated into the paper and create a hydrophobic barrier that repels liquid and creates a contact angle of greater than 135 degrees. This novel platform does not require precision equipment to create hydrophobic barriers; therefore, the cost of manufacturing is significantly reduced without losing the ability to create complex networks. Additionally, the minimal required equipment allows for this technology to be accessed in remote and poverty stricken areas. In another embodiment, the cPMD of the present invention may have networks further paired with pneumatic lifting gates, as well as other typical cPMD features.

The device may be used for screening of unknown specificities as well as for detection of specific immunoglobulins. By depositing many spots with known material, for example protein or DNA, etc., it is possible to rapidly screen for which binder(s) there are in a sample that are specifically binding to the material in particular spot(s). An example is sample determination of specific IgE, wherein the spots contain different allergens. Another example is for screening of libraries (DNA, antibodies, etc.) for different reactivities.

The number of spots per flow matrix is preferably 5-1000, and more preferably 10-100. The spots are preferably smaller than 1 mm in diameter, preferably smaller than 0.5 mm in diameter. The spots are preferably arranged in a pattern that allows for detection of cross reactive analytes or specificities. This is exemplified by allergens having cross-reacting IgE, i.e. such allergens should not be arranged in the same flow line.

The flow matrix may be a porous membrane, such as nitro-cellulose or a strip of solid material. The capture agents may be antibodies or an immunoactive fragment thereof. Alternatively, the capture agents are allergens or an immunoactive fragment thereof In another alternative, the capture agents are DNA/RNA, preferably single stranded or aptameres.

In a preferred embodiment of the device some of the spots functions as positive control(s) and/or internal calibrator(s). The sample is whole blood, serum, plasma, saliva or urine. The label of the labelled second binding reagent is, for example a fluorophore or a chromophore.

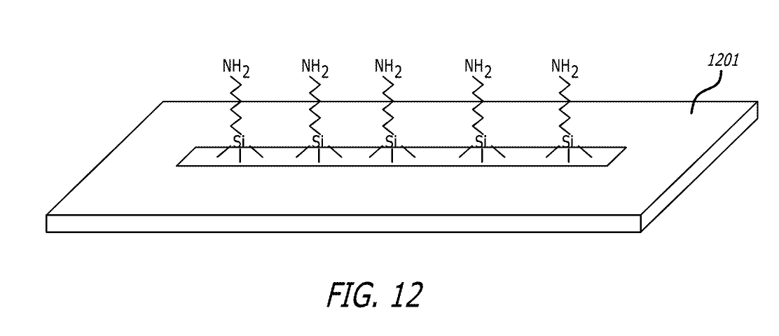

In another embodiment, the present invention is a cPMD comprising a multilayer capability. In another embodiment, the present invention includes multilayer capability having chromatographic paper and nitrocellulose paper, which carries a highly positive charge so that various biomolecules can be immobilized with charge interaction. Once the hydrophobic barriers are formed on a paper, hydrophilic area can be modified with silanes having various functional group. FIG. 12 shows how to generate amine functional group on the hydrophilic side with APTES ((3-Aminopropyl)triethoxysilane). With this functionalization, various biomolecules such as DNA, antibody or other proteins can be immobilized without any additional layers or materials.

The examples below provide illustrative embodiments of the present invention. While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

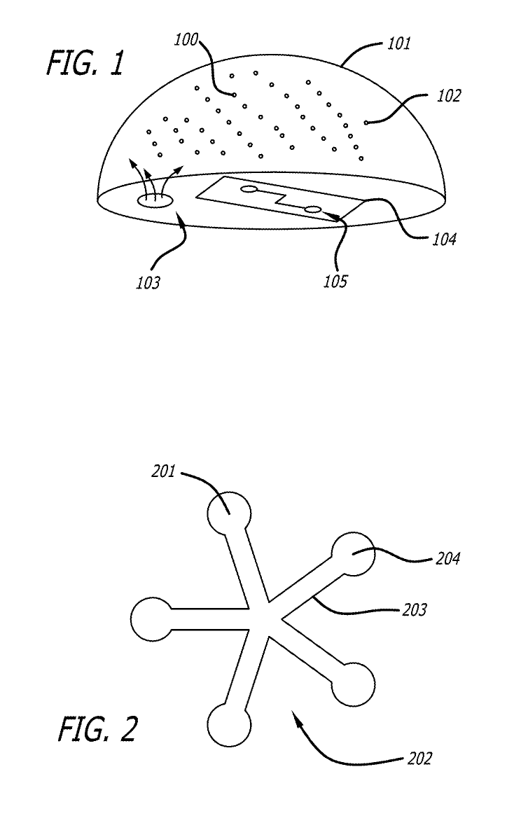

In an exemplary embodiment, the first step to create the sample was to draw the desired shape using AUTOCAD and cut on vinyl tape with a GRAPHTEC ROBO Pro. Turning to FIG. 1, a shaped tape 105 is then placed on chromatographic paper 104. Both TCS 103 and the taped paper were placed in a reaction chamber 101 with a heat block at 60° C. to perform a chemical vapor deposition, wherein the TCS 103 is vaporized into TCS particles 102 within the reaction chamber 101. After a duration of time, such as 5-8 minutes, in the reaction chamber the shaped tape 105 was removed and the paper 104 was tested with a food dye. In an exemplary embodiment, the reaction chamber comprises a vacuum chamber 100.

FIG. 2 shows a successful single input multiple output sample. By adding antigens on each circle, a simple IgG quantification was performed. The red area 201 is the hydrophilic region of the sample and the white area 202 is the hydrophobic region created by TCS (dimension of channels 203: 1.5-mm by 5-mm and diameter of wells 204: 3-mm).

With the chemically patterned papers, the relationship between settling time and channel size, and how the flow rate of the created channel differs from unaltered paper. In order to determine the proper settling time for the hydrophilic channels, an iterative approach was performed with the area of different channels (4, 2, 1, 0.5-mm width and 15-mm length) at different settling times (2, 5, 8, 12 min). After analyzing the data, it was determined there was a linear relationship between settling time and area of the channel. At a 2 min settling time, the front area of the 4-mm channel was 106% of the original and at 12 min settling time the area was 91% the original. This data can be used to create any channel shape that will perfectly match the original mold. Additionally, the flow rate of the channels before and after the chemical application was compared. The results showed that there was no significant difference before and after the chemical modification. With this design, copper, E-coil, lead, and IgG assays were also performed to demonstrate the capabilities of environmental and biomedical markers detection.

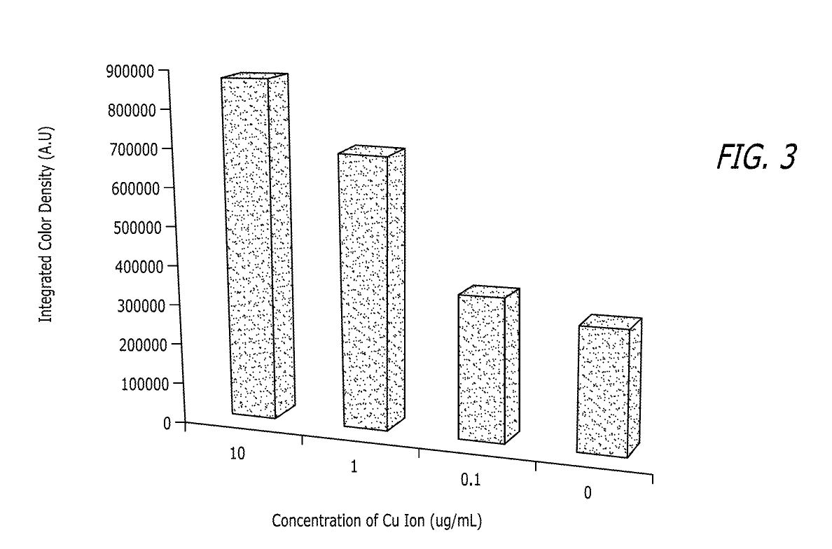

Using a shape similar to the one seen in FIG. 2, the copper results are presented in FIG. 3. The copper ion detection results 300 also showed a linear trend where integration density increases with ion concentration.

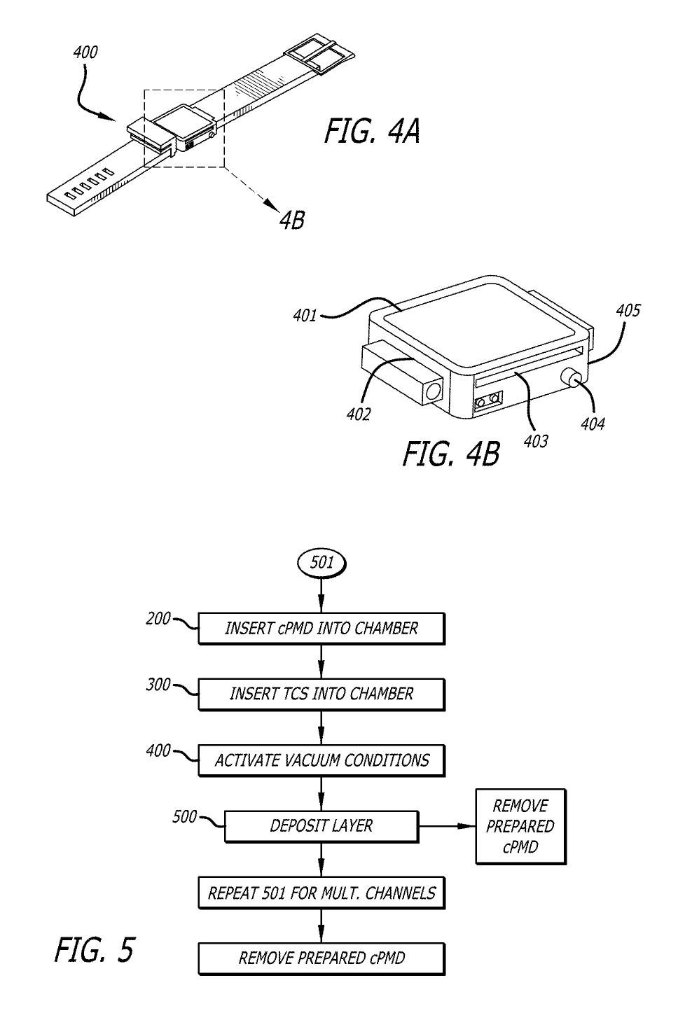

In an exemplary embodiment of the present invention, a diagnostic watch utilizing the present invention was designed to read and display the results of chemically patterned paper-microfluidic device (cPMD). Turning to FIG. 4, for quantifying a biomolecule in samples, the paper comprising the microfluidic device can first be placed inside the diagnostic watch 400. Once a sample has been placed on the inlet of diagnostic watch aligned with a spot on the microfluidic paper 403, the sample will flow through a pre-defined channel and react with a spot where is pre-functionalized with enzyme. After reaction, the results of the test can be determined and displayed to the user of the diagnostic watch via the display screen 401. This watch uses the full potential of the microfluidic paper because it can provide real-time results in remote locations. FIG. 4, the diagnostic watch is composed of a small display screen 401, a microcontroller and battery 405, input buttons 404, and color sensors 402, which is all inside a watch-like frame that attaches to ones wrist. When the user takes a sample and places the microfluidic paper inside the watch 400, the buttons are used to select the type of test being conducted. Once selected, the color sensor 402 and a backlight are used to measure the color and intensity of the result on the paper. The microcontroller 405 then compares this measurement with a pre-programmed database. Once a match has been found, the corresponding results are displayed on the low-power screen, as shown in FIG. 4.

FIG. 5 provides a flow diagram 501 of the CVD process for preparing a cPMD, wherein a CVD process is utilized to impregnate TCS into the paper and create a hydrophobic barrier that repels liquid and creates a contact angle of greater than 135 degrees. In yet another embodiment, the water contact angle is greater than 120 degrees. A first step involves inserting a cPMD into a chamber 200. TCS is also entered into the chamber 300, which may occur before, concurrently, or after insertion of the cPMD. Atmospheric conditions are then activated 400, which may further be under vacuum conditions. A layer of TCS is then deposited 500 via activation of CVD process. In the event multiple channels are involved, process 501 (200, 300, 400, and 500) may be repeatable. Following the process 501, the prepared cPMD may be removed and additional cPMDs may be treated. In another embodiment, the cPMDs may be prepared using a continuous process involving roll-like paper materials which may be treated and cut using said continuous process.

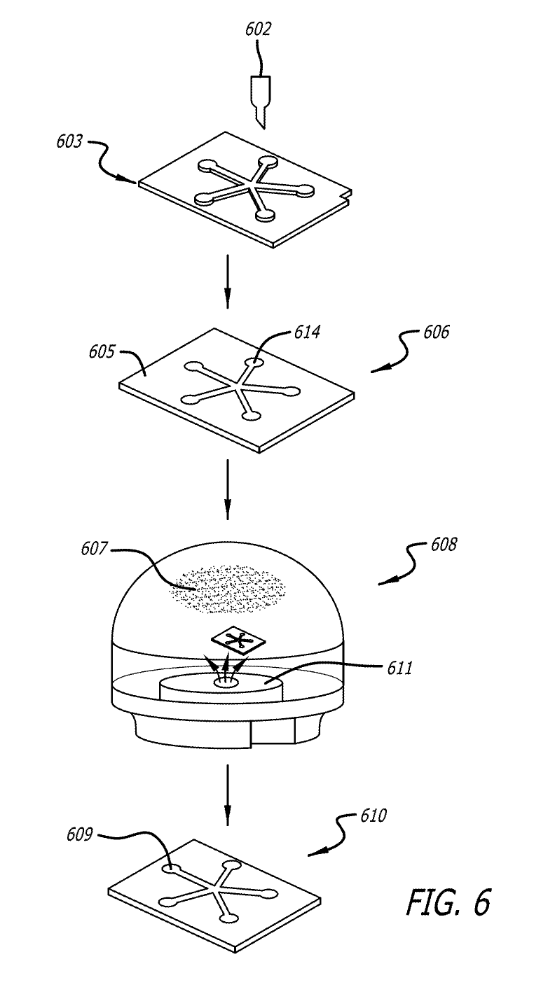

Turning to FIG. 6, shows the development of paper-based microfluidic platform using cPMD method and schematic illustration of fabrication process: A vinyl tape 603 was cut 602 based on a design file, and then transferred onto 4.5×5 cm chromatography paper 605 having the retained vinyl tape 614. The design file may be a CAD or AUTOCAD software, or other known design or modeling software, and exported in a 2-D or 3-D surface format, including IGES, STL, or OBJ file formats, a file is imported into the computer program instructions via a communication link or network. A texture map image of a design can also be imported into the computing device. A computing device may be capable of sending or receiving signals, such as via a wired or wireless network, or may be capable of processing or storing signals, such as in memory as physical memory states, and may, therefore, operate as a server. Thus, computing devices may include, as examples, dedicated rack-mounted servers, tablets, smart phones, watches, hand-held devices, sensor devices, desktop computers, laptop computers, set top boxes, integrated devices combining various features, such as two or more features of the foregoing devices, or the like. Computing devices may vary widely in configuration or capabilities, but generally a server may include one or more central processing units and memory. A server may also include one or more mass storage devices, one or more power supplies, one or more wired or wireless network interfaces, one or more input/output interfaces, or one or more operating systems, such as Windows Server, Mac OS X, Unix, Linux, FreeBSD, or the like.

The patterned paper 606 is placed into the vacuum chamber 608 with 100 μL it of TCS solution placed on a 60° C. heat block 611. After vacuum process 607, the tape was removed, and fluidic pattern was ready for bioassay. Both a positive and negative feature of 2D-channel systems with multiple color depositions using cPMD, as well as multi-layered paper-microfluidic network using cPMD technique, and a cPMD sample 610 with complex fluidic pattern 609 may be created via the CVD method. On backside of the device, interconnection channels network was developed to make the flow from one channel to others.

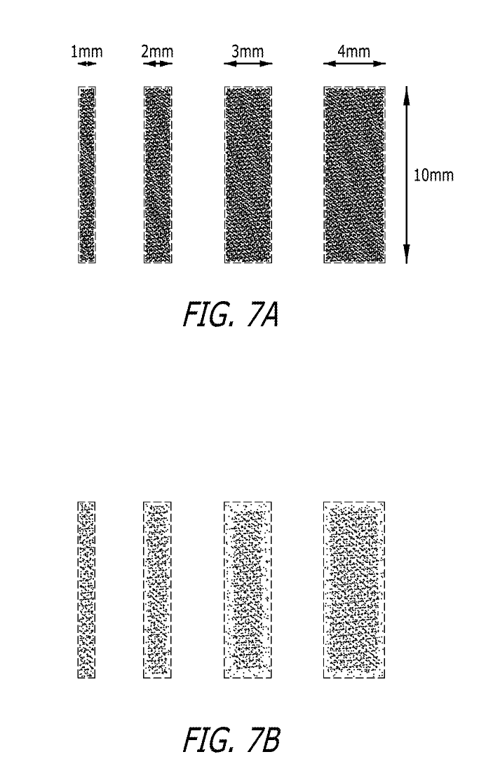

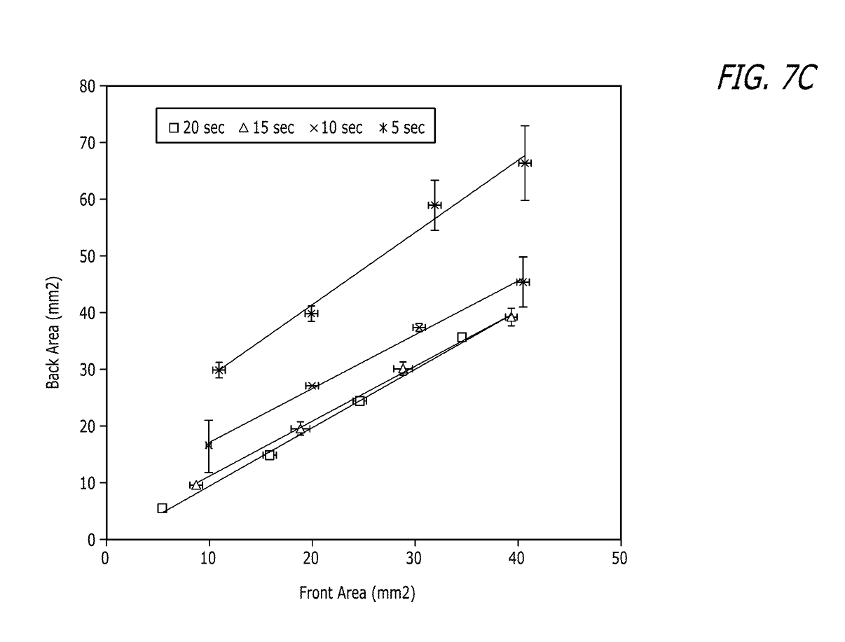

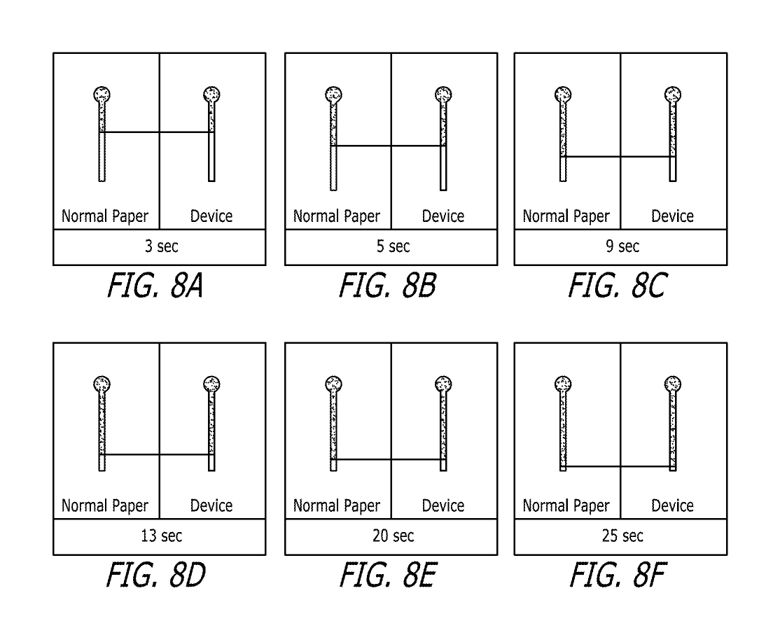

Turning to FIG. 7A-7C, characterization of the cPMD technique described in FIG. 6 is modulated by controlling settling time and channel area FIG. 7A characterizes the front side of the patterned chromatography paper at 15 seconds settling time. FIG. 7B characterizes the back side of the patterned chromatography paper at 15 seconds settling time. FIG. 7C charts the different dimensions of channels (4, 3, 2, 1 mm width×10 mm length) as analyzed with different settling times (20 s, 15 s, 10 s, 5 s). FIG. 8A-8F show volumetric flow rate analysis on normal paper and patterned fluidic device with a dye solution. A dye color solution was applied onto both untreated chromatography paper and treated paper-based microfluidic device to demonstrate the different time point flow rate.

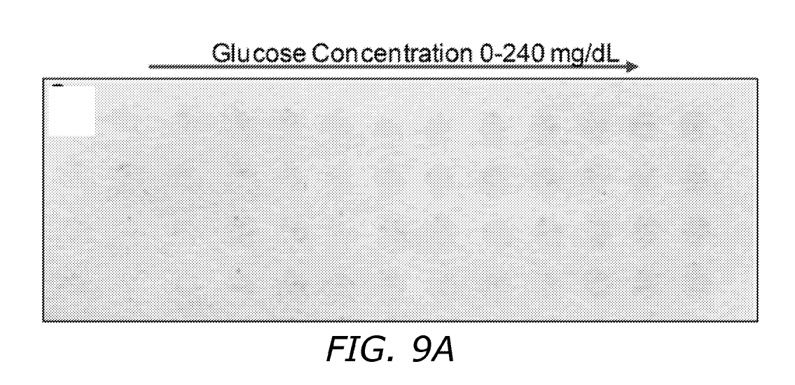

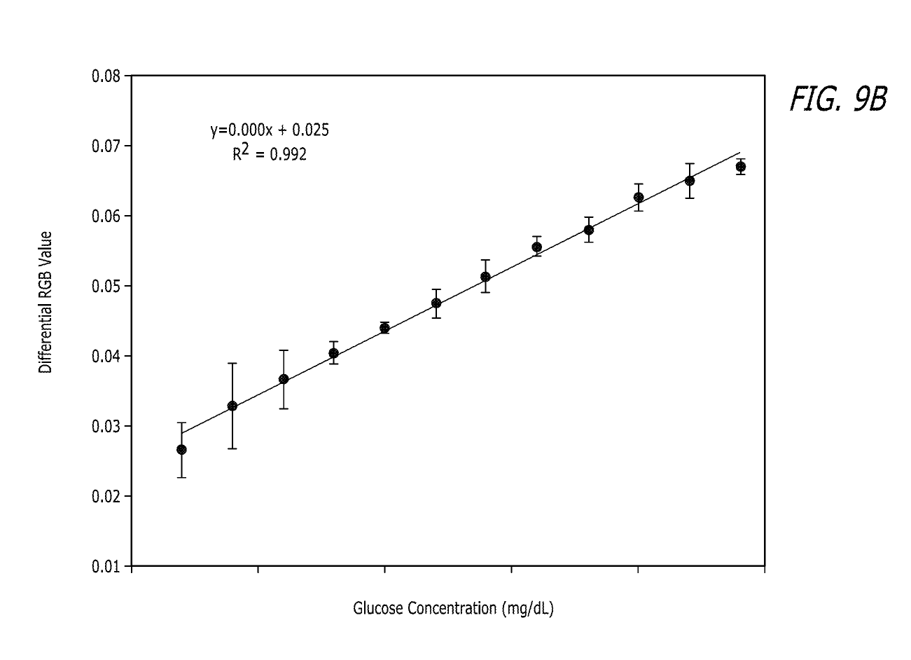

FIG. 9A-9B provide a demonstration of a glucose assay on spot patterned cPMD. FIG. 9A provides a spot assay having different concentrations of glucose solutions (left to right; 0-240 mg/dL), as an exemplary, but non-essential configuration of the present invention, were applied onto each spot on cPMD device. FIG. 9B shows the glucose assay results acquired by iColormeter app on a smartphone. These results show a good linear relationship between glucose concentrations and differential RGB value.

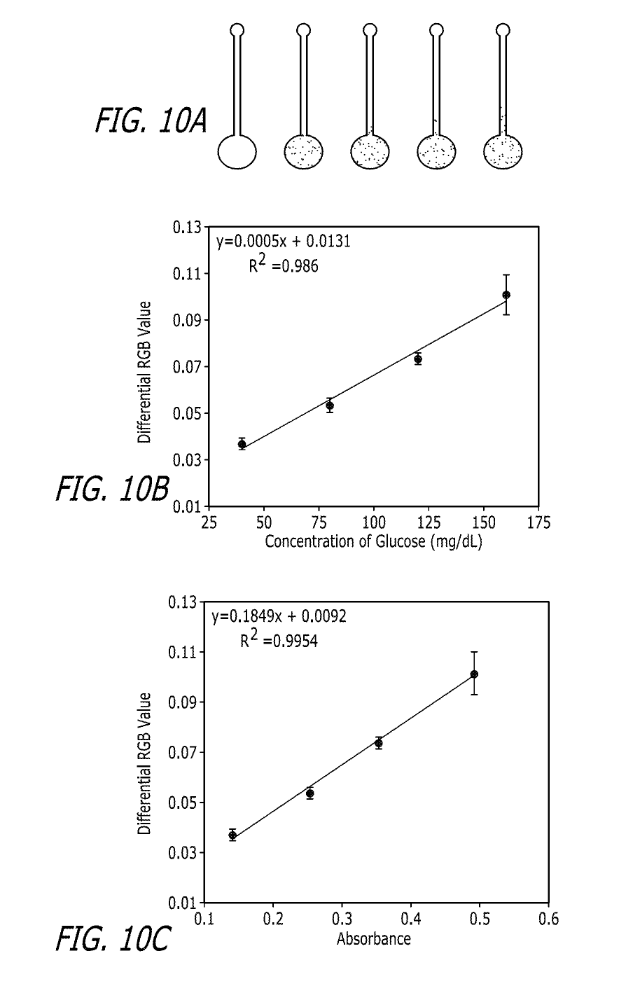

FIG. 10A-10C provide demonstration of inflow glucose assay on a cPMD of the present invention: FIG. 10A shows an exemplary, but non-essential configuration of a glucose assay with various concentrations of glucose (left to right: 0, 40, 80, 120, 160 mg/dL) was analyzed on lateral inflow cPMD pattern. An assay reagent was added into the big circle reaction area, the other end of channel allowed glucose solution to flow freely into the reaction area and it caused color formation. FIG. 10B results show a linear relationship between various concentrations of glucose and their differential RGB values. FIG. 10C plots absorbance obtained from 96-well plate and differential RGB value from inflow assay demonstrates the linear relationship.

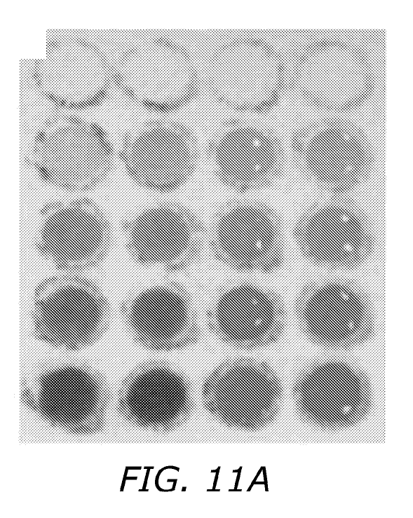

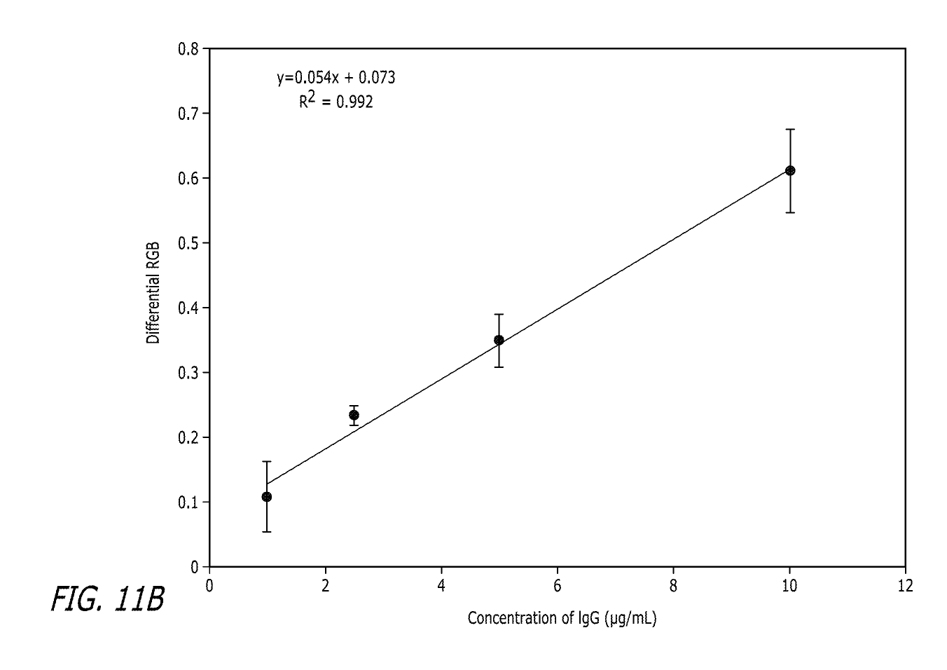

FIG. 11A-11B provide an immunoassay on well spot cPMD. Turning to FIG. 11A, at the first two columns of spotted cPMD, various concentration of IgG (1.25-10 μg/ml) enzymatically reacted with HRP and TMB that shows colored dots based on the concentration, and two other columns show the changes of final solution color (blue to green as a non-limiting, non-essential example) after adding a stop solution. FIG. 11B shows assay results acquired by ICOLORMETER on a smart phone computing device, which shows the linear relationship between differential RGB value and IgG concentrations.

The paper-based microfluidic platform as disclosed in accordance with the exemplary embodiments set forth herein is repeatable, versatile, and cost effective. The chemical application allows for the creation of complex channels. A wide variety of channels can be created using the settling time calculated from the calibration results. The new method does not affect the properties of the paper in the hydrophilic channel area.

Those skilled in the art will recognize that the devices, methods, and systems of the present invention may be implemented in many manners and as such are not to be limited by the foregoing exemplary embodiments and examples. Furthermore, the embodiments of methods presented and described in this disclosure are provided by way of example in order to provide a more complete understanding of the technology. The disclosed methods are not limited to the operations and logical flow presented herein. Alternative embodiments are contemplated in which the order of the various operations is altered and in which suboperations described as being part of a larger operation are performed independently.

What is claimed is:

1. A method for preparing a chemically patterned microfluidic device, comprising:
a. providing a chemical vapor deposition (CVD) reactor chamber;
b. positioning within the chemical vapor deposition (CVD) reactor chamber a substrate; and
c. forming over the substrate a layer comprising at minimum a first reactant source material introduced into the reactor chamber.

2. The method of claim 1, wherein said substrate is a porous membrane.

3. The method of claim 1, wherein said substrate is chromatographic paper.

4. The method of claim 1, further comprising a substrate having multiple layers.

5. The method of claim 1, further comprising positioning a multilayer substrate having more than one layer of substrate selected from group consisting of: chromatographic paper and nitrocellulose.

6. The method of claim 1, further comprising depositing capture agents selected from the group consisting of: a protein, an antibody, an enzyme, and immunoactive fragment, an allergen, DNA, RNA, aptamers, or combinations thereof.

7. The method of claim 1, wherein said reactor chamber is a vacuum chamber.

8. The method of claim 1, wherein said layer is a hydrophobic layer.

9. The method of claim 1, wherein said layer is a silane

10. The method of claim 8, wherein said hydrophobic layer has a water contact angle greater than 120 degrees.

11. The method of claim 8, wherein said hydrophobic layer has a water contact angle greater than 135 degrees.

12. The method of claim 1, wherein the temperature on the surface of the reactor chamber is from 10 deg. C. to 100 deg. C.

13. The method of claim 1, wherein the temperature on the surface of the reactor chamber is 60 deg. C.

14. A chemically patterned microfluidic device, comprising a porous membrane substrate having at least one channel, wherein said substrate further comprises a deposited functional layer.

15. The device of claim 14, wherein said porous membrane substrate is a paper substrate.

16. The device of claim 14, wherein said porous membrane substrate is chromatography paper.

17. The device of claim 14, wherein said functional layer is a hydrophobic layer.

18. The device of claim 17, wherein said hydrophobic layer is comprised of a silane.

19. The device of claim 14, wherein said deposited functional layer has a water contact angle greater than 120 degrees.

20. The device of claim 14, wherein said deposited functional layer has a water contact angle greater than 135 degrees.

21. The device of claim 14, wherein said device further comprises a computing device for quantitative measurement of the reaction of fluid within the at least one channel and display via a display screen.

22. The device of claim 14, wherein said device further comprises a wearable sensor device.

23. The device of claim 14, wherein the at least one channel is functionalized with a capture agent selected from the group consisting of: a protein, an antibody, an enzyme, an immunoactive fragment, an allergen, DNA, RNA, aptamers, or combinations thereof.

24. The device of claim 14, further comprising multilayer substrate having more than one layer of substrate selected from group consisting of: chromatographic paper and nitrocellulose.
